(19) United States
(12) Patent Application Publication
(10) Pub. No.: US 2026/0194574 A1
(43) Pub. Date: Jul. 9, 2026

(54) TESTING APPARATUS FOR OVER-THE-AIR TESTING

(71) Applicant: JCET STATS ChipPAC Korea Limited, Incheon (KR)

(72) Inventors: JeongHyeop LEE, Incheon (KR); KiHeon JEONG, Incheon (KR); YoungHyun KIM, Incheon (KR)

(21) Appl. No.: 19/440,594

(22) Filed: Jan. 5, 2026

(30) Foreign Application Priority Data
Jan. 6, 2025 (CN) 202510017308.5

(51) Int. Cl. G01R 31/311; G01R 31/28

(52) U.S. Cl. CPC G01R 31/311; G01R 31/2822; G01R 31/2879

(57) ABSTRACT

A testing apparatus for OTA testing is provided. The testing apparatus comprises: a device connection circuit board, a reference device seat and a device under test (DUT) seat. The device connection circuit board has a front surface, and a back surface. The reference device seat is supported at a front side of the device connection circuit board. The reference device seat comprises a reference device cavity and a first set of openings. The DUT seat is supported at the front side of the device connection circuit board and is farther away from the device connection circuit board than the reference device seat. The DUT seat at least overlaps with the reference device seat at the first set of openings of the reference device seat. The DUT seat comprises a DUT cavity and a second set of openings.

### TECHNICAL FIELD

The present application generally relates to semiconductor technology, and more particularly, to a testing apparatus for Over-The-Air (OTA) testing.

### BACKGROUND

An apparatus that utilizes a wired connection-based testing method to test a device under test (DUT) is referred to as a wired connection testing apparatus. FIG. 1 illustrates a block diagram of a wired connection testing apparatus 100. As depicted in FIG. 1, a DUT 110 and a reference device 120 are both mounted on a test circuit board 130. The DUT 110 and the reference device 120 can communicate with each other via a wired cable 140, which may be a pogo pin or a copper trace of a test circuit board. However, when devices equipped with radio frequency (RF) ports are under test, the wired connection testing method introduces inaccuracies into test results of the devices. Moreover, air interface performance of the DUTs, especially their performance through inter-device signal transmission via electromagnetic waves propagating in the air, cannot be tested and verified.

To accurately test a DUT equipped with RF port(s) and evaluate its air interface performance, an Over-The-Air (OTA) testing method is proposed. When the OTA testing method is implemented, wireless communication is established between the DUT and the reference device without requiring a wired connection. However, existing OTA testing devices exhibit certain deficiencies that limit the precision of the OTA testing.

Therefore, a need exists for a testing apparatus that is suitable for OTA testing.

### SUMMARY

An objective of the present application is to provide a testing apparatus for OTA testing.

According to an aspect of embodiments of the present application, a testing apparatus is provided. The testing apparatus comprises: a device connection circuit board having a front surface, and a back surface; a reference device seat supported at a front side of the device connection circuit board, wherein the reference device seat comprises: a reference device cavity for receiving a reference device; and a first set of openings formed at a side of the reference device cavity away from the device connection circuit board, and configured to expose a set of RF ports of the reference device received within the reference device cavity; and a device under test (DUT) seat supported at the front side of the device connection circuit board and farther away from the device connection circuit board than the reference device seat; wherein the DUT seat at least overlaps with the reference device seat at the first set of openings of the reference device seat, and wherein the DUT seat comprises: a DUT cavity for receiving a DUT; and a second set of openings formed at a side of the DUT cavity facing the device connection circuit board and in a region of the DUT seat overlapping with the reference device seat, wherein the second set of openings are aligned with the first set of openings; and wherein the second set of openings are configured to expose a set of RF ports of the DUT received within the DUT cavity to allow communication between the DUT and the reference device through the two sets of RF ports aligned with each other.

It is to be understood that both the foregoing general description and the following detailed description are exemplary and explanatory only, and are not restrictive of the invention. Further, the accompanying drawings, which are incorporated in and constitute a part of this specification, illustrate embodiments of the invention and together with the description, serve to explain principles of the invention.

### BRIEF DESCRIPTION OF THE DRAWINGS

The drawings referenced herein form a part of the specification. Features shown in the drawing illustrate only some embodiments of the application, and not of all embodiments of the application, unless the detailed description explicitly indicates otherwise, and readers of the specification should not make implications to the contrary.

FIG. 1 is a block diagram of a wired connection testing apparatus which transmits signals via a wired cable.

FIG. 2 is a block diagram of a testing apparatus for OTA testing according to an embodiment of the present application.

FIG. 3 is a structural diagram of a testing apparatus according to an embodiment of the present application.

FIG. 4 is a structural diagram of a DUT cavity of the testing apparatus shown in FIG. 3.

FIG. 5 is a structural diagram of a testing apparatus according to another embodiment of the present application.

FIG. 6 is a structural diagram of a testing apparatus according to another embodiment of the present application.

The same reference numbers will be used throughout the drawings to refer to the same or like parts.

### DETAILED DESCRIPTION OF THE PREFERRED EMBODIMENTS

The following detailed description of exemplary embodiments of the application refers to the accompanying drawings that form a part of the description. The drawings illustrate specific exemplary embodiments in which the application may be practiced. The detailed description, including the drawings, describes these embodiments in sufficient detail to enable those skilled in the art to practice the application. Those skilled in the art may further utilize other embodiments of the application, and make logical, mechanical, and other changes without departing from the spirit or scope of the application. Readers of the following detailed description should, therefore, not interpret the description in a limiting sense, and only the appended claims define the scope of the embodiment of the application.

In this application, the use of the singular includes the plural unless specifically stated otherwise. In this application, the use of “or” means “and/or” unless stated otherwise. Furthermore, the use of the term “including” as well as other forms such as “includes” and “included” is not limiting. In addition, terms such as “element” or “component” encompass both elements and components including one unit, and elements and components that include more than one subunit, unless specifically stated otherwise. Additionally, the section headings used herein are for organizational purposes only, and are not to be construed as limiting the subject matter described.

As used herein, spatially relative terms, such as “beneath”, “below”, “above”, “over”, “on”, “upper”, “lower”, “left”, “right”, “vertical”, “horizontal”, “side” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The device may be otherwise oriented (rotated 90 degrees or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

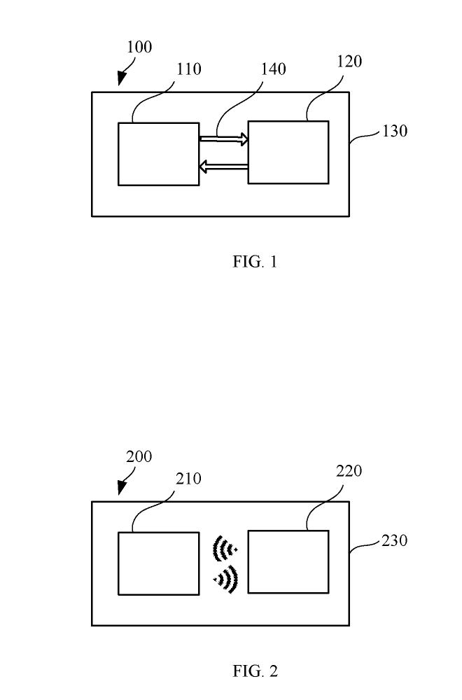

FIG. 2 illustrates a testing apparatus 200 for OTA testing according to an embodiment of the present application. In some embodiments, the testing apparatus 200 can be used to test a device under test (DUT) equipped with RF ports. RF ports are transmission or reception ports, or transceiver ports (i.e., signal input/output ports), which are capable of transmitting signals in a wireless RF form. RF ports may include 5G ports, Wi-Fi ports, Bluetooth ports, and the like. Typically, the RF port may exhibit certain signal directionality, meaning that when a paired RF port of another device is roughly aligned with or directed to the RF port, a strength and/or speed of a wireless signal transmitted between the two ports is optimal.

In some embodiments, the DUT can be a component-level device, such as an antenna-in-package (AiP) module or other packaged or unpackaged semiconductor components. The DUT can also be a system-level device, such as a mobile phone. Unlike traditional devices with antennas mounted on printed circuit boards (PCBs), the AiP module can integrate semiconductor chip(s) and antenna(s) into a single package unit. The AiP modules are mainly for wireless communication, such as 5G, Wi-Fi, or Bluetooth communication. The integration results in a smaller size, enhanced electrical performance, improved signal integrity and power integrity, and reduced costs.

As shown in FIG. 2, the testing apparatus 200 includes a DUT 210 and a reference device 220. The DUT 210 and reference device 220 are mounted on a test circuit board 230 and preferably electrically coupled to the test circuit board 230 for signal interaction. For example, the DUT 210 and the reference device 220 can receive power supply, control signals, or drive signals from the test circuit board 230. The DUT 210 and the reference device 220 can also send feedback signals or test data/results to the test circuit board 230. Additionally, the DUT 210 and the reference device 220 can communicate wirelessly through at least one pair of RF ports, thereby implementing the testing of the DUT 210. Generally, an automatic test equipment (ATE, not shown) is required to place the DUT 210 and the reference device 220 on the test circuit board 230. An automated mechanical transfer device (such as robotic arms) may be used to move the DUT 210 and align at least one pair of RF ports between the DUT 210 and the reference device 220 with each other to meet requirements on signal connection for the OTA testing. A high level of accuracy in operation for the ATE is thus desired.

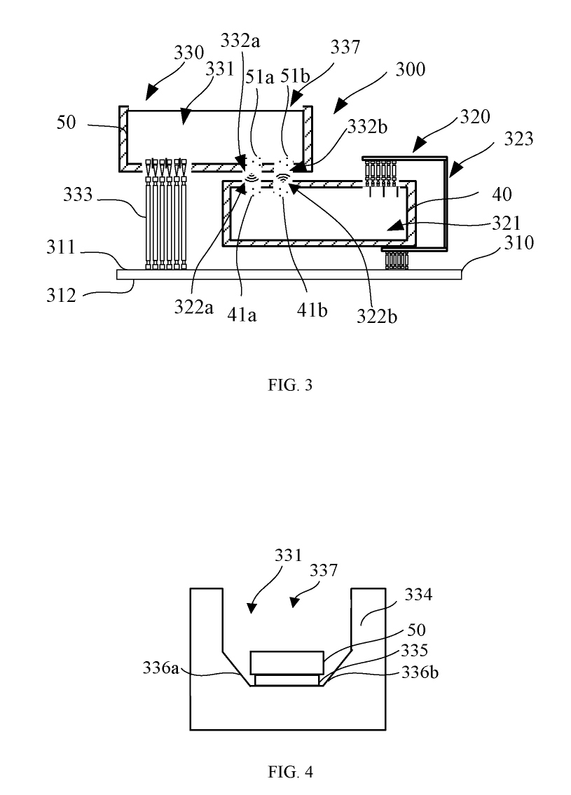

To align the RF ports of the DUT and the reference device with each other, a testing apparatus for OTA testing is provided in the present application. The testing apparatus is capable of aligning the RF ports of devices with each other with a relatively simple structure. FIG. 3 illustrates a structural diagram of a testing apparatus 300 according to an embodiment of the present application.

As shown in FIG. 3, the testing apparatus 300 includes a device connection circuit board 310, a reference device seat 320, and a DUT seat 330. The reference device seat 320 is used for mounting or placing a reference device 40, and the DUT seat 330 is used for mounting or placing a DUT 50. The device connection circuit board 310 has a front surface 311 and a back surface 312. The reference device seat 320 and the DUT seat 330 can be supported on or above the front surface 311, e.g., through brackets, frames, or housings (not shown). For example, the reference device seat 320 and the DUT seat 330 can be supported above the front surface 311 of the device connection board 310, preferably at different heights above the front surface 311.

In some embodiments, the device connection circuit board 310 can be electrically coupled to an external circuit to drive the reference device 40 and the DUT 50 or receive feedback signals or test data/results from the reference device 40 and the DUT 50. For example, the device connection circuit board 310 can be mounted and electrically coupled to another control circuit board or another host device via connectors, ports, or similar electrical connection components on the back surface 312. Alternatively, in some embodiments, the device connection circuit board 310 can integrate or be mounted with an automatic test module, which can run an automated test program to operate the reference device 40 and the DUT 50, without the need for connecting additional external circuits.

The reference device seat 320 includes a reference device cavity 321 for receiving the reference device 40. Specifically, the reference device cavity 321 has a side farther away from the device connection circuit board 310 and another side close to the device connection circuit board 310. The reference device seat 320 also includes a first set of openings (e.g., two openings 322a and 322b shown in FIG. 3) formed at the side of the reference device cavity 321 away from the device connection circuit board 310. The first set of openings 322a and 322b expose a set of RF ports (ports 41a and 42b shown in FIG. 3) of the reference device 40 received within the reference device cavity 321. In the embodiment shown in FIG. 3, the first set of openings 322a and 322b face towards the DUT seat 330, or more specifically, towards the DUT 50 placed in the DUT seat 330. In some embodiments, the reference device 40 can be a device capable of pairing and communicating with the DUT 50. For example, the reference device 40 can be of the same model as the DUT 50 or a different model from the DUT 50, provided that the RF port of the reference device 40 operates within the same frequency range and supports the same RF communication protocol as the DUT 50. The reference device 40 can be a highly calibrated device, such as a Golden Device. The Golden Device refers to a good sample of the DUT that has the optimal specifications.

It can be appreciated that while the first set of openings are shown as including two openings in FIG. 3, the number of openings in the first set of openings can vary depending on the specific embodiment like the number of the RF ports included in the DUT. For example, the first set of openings can include one or more openings. For a reference device with a single port with an integrated transmission and reception capability, the first set of openings can include one opening. However, for a DUT with multiple transmission and reception ports which need to be tested, the first set of openings can include multiple corresponding openings. Taking a reference device with ports having separate transmission and reception capabilities as an example, the first set of openings can include two openings (e.g., openings 322a and 322b) to test the transmission port and the reception port individually.

In addition to allowing wireless RF communication between the reference device and the DUT, the reference device seat 320 also includes a first set of electrical connection components 323 to electrically couple the reference device 40 received within the reference device cavity 321 to the device connection circuit board 310. The reference device 40 can receive power or signals from the device connection circuit board 310, or send feedback signals to the device connection circuit board 310 through the first set of electrical connection components 323.

Still referring to FIG. 3, the DUT seat 330 is supported farther away from the device connection circuit board 310 than the reference device seat 320, but at least overlaps with the reference device seat 320 at the first set of openings 322a and 322b. The DUT seat 330 includes a DUT cavity 331 for receiving the DUT 50. The DUT cavity 331 has one side facing the device connection circuit board 310, and another side away from the device connection circuit board 310. At the side away from the device connection circuit board 310, the DUT seat 330 includes a device loading opening 337 connected with the DUT cavity 331, allowing the DUT 50 to be received within the DUT cavity 331. When the testing apparatus 300 is set up in a manner and orientation as shown in FIG. 3, such as when it is placed on a test platform or machine, the device loading opening 337 can be orientated upwards, facilitating the automated loading of the DUT into the DUT seat 330. This loading component is advantageous for an automated testing system, as it improves the efficiency of loading and testing.

At the side of the DUT cavity 331 facing the device connection circuit board 310, the DUT seat 330 includes a second set of openings (e.g., two openings 332a and 332b shown in FIG. 3). The second set of openings 332a and 332b are formed in a region of the DUT seat 330 overlapping with the reference device seat 320, and are aligned with the first set of openings 322a and 322b, respectively. The second set of openings 332a and 332b are used to expose a set of RF ports (e.g., ports 51a and 51b shown in FIG. 3) of the DUT 50 received within the DUT cavity 331. The set of RF ports 51a and 51b can be a transmission port and a reception port, respectively. Similar to the first set of openings, the number of openings in the second set of openings corresponds to the number of openings in the first set of openings. The second set of openings can include one or more openings, and there is no specific limitation to the number of openings in this embodiment. In the embodiment shown in FIG. 3, the first set of openings 322a and 322b are aligned with the second set of openings 332a and 332b, respectively, so that the RF ports 41a and 41b of the reference device 40 exposed through the first set of openings 322a and 322b are aligned with the RF ports 51a and 51b of the DUT 50 exposed through the second set of openings 332a and 332b. Thus, the DUT 50 and the reference device 40 can communicate with each other through the two sets of aligned RF ports.

The DUT seat 330 further includes a second set of electrical connection components 333, for electrically coupling the DUT 50 received within the DUT cavity 331 to the device connection circuit board 310. The DUT 50 receives driving signals from the device connection circuit board 310 through the second set of electrical connection components 333, or further, outputs feedback signals generated by the DUT 50 to the device connection circuit board 310.

Because the first set of openings 322a and 322b are aligned with the second set of openings 332a and 332b, through the exposure of the RF ports 41a and 41b of the reference device 40 by the first set of openings 322a and 322b, as well as the exposure of the RF ports 51a and 51b of the DUT 50 by the second set of openings 332a and 332b, the alignment of the RF ports 51a and 51b of the DUT 50 with the RF ports 41a and 41b of the reference device 40 can be achieved. In the aligned state, the communication quality between the DUT 50 and the reference device 40 is improved, thus the accuracy of the testing is enhanced.

In some embodiments, the alignment of the second set of openings with the first set of openings does not require an absolute alignment, rather, certain deviation in position is permitted. For example, a maximum deviation may be a certain percentage such as 10% of a size of an opening in the first set of openings or the second set of openings, or a certain percentage such as 10% of a size of the RF port. Furthermore, in cases where the first and second sets of openings each include multiple openings, the positions of the openings and distances among the openings in each set should correspond to a layout of the RF ports of the reference device or the DUT. Typically, when one opening in the set of openings is aligned with one RF port of the device, the other openings in the set of openings can also be aligned with the corresponding RF ports of the device.

FIG. 4 shows a cross-sectional diagram of the DUT cavity 331 in the testing apparatus 300 illustrated in FIG. 3. As shown in FIG. 4, the DUT cavity 331 includes a guide member 334. The guide member 334 is formed within the DUT cavity 331, and used to guide the DUT 50 to move to a predetermined test position 335 within the DUT cavity 331. The test position 335 is a position that allows alignment between the set of RF ports of the DUT and the second set of openings 332.

It is understood that, during the actual testing, operational errors may occur when the ATE places the DUT into the DUT cavity, resulting in misalignment between the RF ports of the DUT and the second set of openings. Therefore, the RF ports may be prevented from being properly exposed, which may affect the testing results. However, by forming a guide member within the DUT cavity, even if there is a certain degree of deviation when the DUT is placed into the DUT cavity, the guide member can guide the DUT to move to the predetermined test position to align the RF ports of the DUT with the second set of openings. The accuracy of the testing is thus improved.

As shown in FIG. 4, in some embodiments, the guide member includes at least one inclined surface, such as two inclined surfaces 336a and 336b. Each inclined surface is inclined relative to a bottom of the DUT cavity 331 to guide the DUT, which enters through the device loading opening, to slide down to the predetermined test position 335 under gravity. At least one inclined surface is positioned between the device loading opening 337 and the bottom of the DUT cavity 331. In the embodiment shown in FIG. 4, the inclined surface 336a may start at an intermediate position of a side wall of the DUT cavity 331 and terminate at the bottom of the DUT cavity 331. In some other embodiments, the inclined surface 336a may alternatively start at the top of the DUT cavity 331, i.e., near the device loading opening, and terminate at the bottom of the DUT cavity 331, or at an intermediate position of its side wall, or at another suitable location.

It should be noted that, in the embodiment shown in FIG. 4, one cross-section of the DUT cavity 331 is described as an example. However, in other embodiments, the DUT cavity 331 may also include inclined surfaces at other cross-sections. For instance, the DUT cavity 331 may have a substantially cuboid structure, with four inclined surfaces formed on two pairs of mutually perpendicular side walls of the cuboid to guide the movement of the DUT within the DUT cavity.

During operation, after the ATE places the DUT into the DUT cavity 331, the DUT enters the DUT cavity 331 through the device loading opening 337. If there is a loading position deviation which renders that the DUT is not directly placed at the predetermined test position 335 at the bottom of the DUT cavity 331 but instead contacts the inclined surface 336, the DUT can slide along the inclined surface 336 to the predetermined test position 335 under the guidance of the inclined surface 336.

FIG. 5 illustrates a structural diagram of a testing apparatus 500 according to another embodiment of the present application.

As shown in FIG. 5, the testing apparatus 500 includes a test region 540 between a first set of openings 522a and 522b and a second set of openings 532a and 532b. The testing apparatus 500 further includes a shielding component 550 mounted around the test region 540, which is used to shield external electromagnetic signals from entering the test region 540.

During the actual testing process, RF ports 51a and 51b of a DUT 50 communicate with RF ports 41a and 41b of a reference device 40 in the test region 540 between the first set of openings 522a, 522b and the second set of openings 532a, 532b. Since this test region 540 is an open region, external electromagnetic signals may enter the test region 540 and interfere with the communication between the devices. However, by providing the shielding component 550, external electromagnetic signals, particularly undesirable interference signals, can be blocked from entering the test region 540, thereby preventing external electromagnetic signals from interfering with the communication between the reference device 40 and the DUT 50.

In some embodiments, the shielding component 550 can include a shielding tape. The shielding tape is an adhesive tape with a metal or similar conductive shielding layer, which can be attached to the reference device seat 520 and the DUT seat 530, positioned between the first set of openings 522a and 522b and the second set of openings 532a and 532b, while leaving the first set of openings 522a, 522b and the second set of openings 532a, 532b exposed. In specific implementations, the shielding tape can entirely cover the test region 540, except the regions where the first set of openings 522a, 522b and the second set of openings 532a, 532b are located, thereby shielding external electromagnetic signals from interfering with the communication between the DUT 50 and the reference device 40.

In some examples, to further support the shielding tape adhered between the first and second sets of openings, the shielding component 550 may further include a support member, such as a support frame or support plate. The support member is mounted around the test region 540 and used to support the shielding tape around the test region in a predetermined shape and size.

In specific implementations, the support member may be a rigid component capable of effectively providing support between the first set of openings 522a, 522b and the second set of openings 532a, 532b. The predetermined shape of the support member may be a regular shape, such as circular or square, or an irregular shape. There is no specific limitation in this embodiment, provided the support member can effectively support the shielding tape within the test region and restrict deformation and movement of the shielding tape. In some embodiments, the support member may surround the test region 540, thereby minimizing the entry of external electromagnetic signals into the test region.

It should be understood that the reference device 40 may not be a permanent part of the testing apparatus 500, and may instead be removably mounted within the reference device cavity 521. The reference device 40 is placed into the cavity when testing of DUTs is being performed or to be performed, and the reference device 40 can be removed from the cavity 521 when no testing is performed. In other embodiments, the reference device 40 itself can be a component of the testing apparatus 500. As shown in FIG. 5, the testing apparatus 500 includes the reference device 40, which is fixedly mounted within the reference device cavity 521. A set of RF ports 41a and 41b of the reference device 40 are exposed through the first set of openings 522. This eliminates the need to reposition the reference device for each test, thereby testing efficiency is improved.

The reference device seat 520 further includes a first set of electrical connection components 523 for electrically coupling the reference device 40 to the device connection circuit board 510. In some embodiments, since the electrical connection ports and RF ports of the reference device 40 are located at the same side and away from the device connection circuit board 510, the first set of electrical connection components 523 can include a first set of pogo pins 5231 located at the side of the reference device seat 520 away from the device connection circuit board 510, and including a first set of contacts 5232 connectable to the reference device and a second set of contacts 5233 opposite to the first set of contacts. It should be understood that, at the position of the first set of contacts 5232, the reference device seat 520 may include an opening to expose a portion of the reference device 40, allowing the reference device 40 to contact and be electrically connected with the first set of contacts 5232. The first set of electrical connection components 523 further include a second set of pogo pins 5234 located between the reference device seat 520 and the device connection circuit board 510, including a third set of contacts 5235 connected to the device connection circuit board 510 and a fourth set of contacts 5236 opposite to the third set of contacts 5235. The first set of electrical connection components 523 can include a flexible connector 5237 which is used to couple the second set of contacts 5233 with the fourth set of contacts 5236. The flexible connector 5237 extends from the front side to the back side of the reference device seat 520. In this way, the reference device 40 can be electrically coupled to the device connection circuit board 510 through the first set of electrical connection components 523. In some embodiments, the flexible connector 5237 may be a flexible printed circuit board.

Similarly, the DUT 50 is electrically coupled to the device connection circuit board 510 through a second set of electrical connection components. In the embodiment shown in FIG. 5, electrical connection ports of the DUT 50 are located at the side of the DUT seat 530 near the device connection circuit board 510, thus only one set of pogo pins are needed to couple the DUT 50 to the device connection circuit board 510. As shown in FIG. 5, the second set of electrical connection components include a third set of pogo pins 5331 located between the DUT seat 530 and the device connection circuit board 510, which are used to couple the DUT 50 with the device connection circuit board 510. It should be understood that, at the position of the third set of pogo pins 5331, the DUT seat 530 can include an opening to expose a portion of the DUT 50, such as the electrical connection ports thereof.

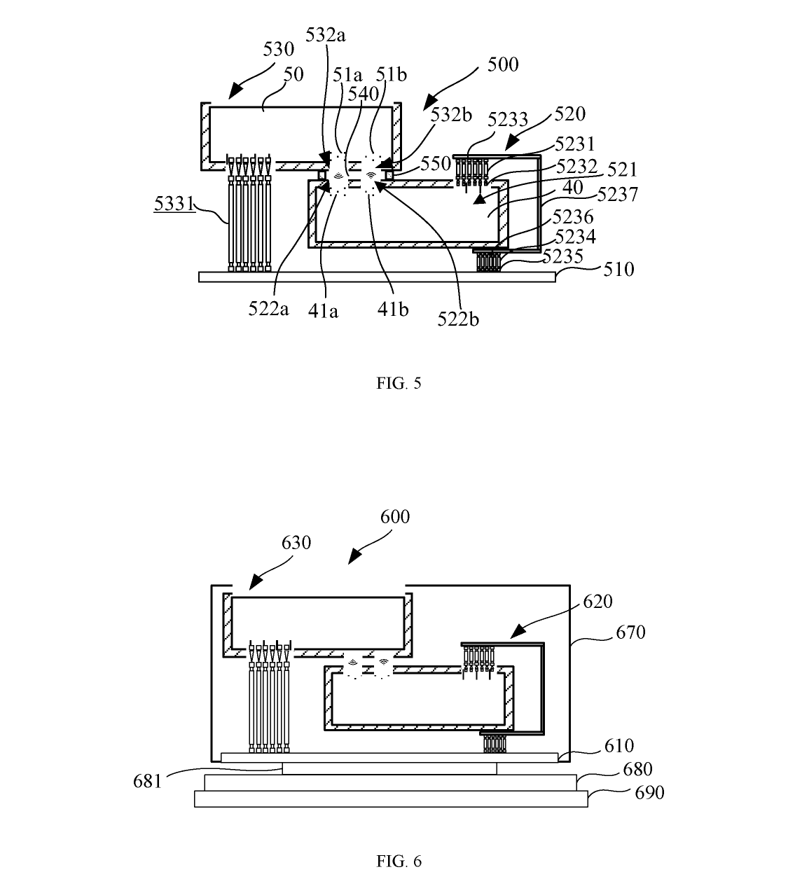

FIG. 6 illustrates a structural diagram of a testing apparatus 600 according to another embodiment of the present application.

As shown in FIG. 6, the testing apparatus 600 includes a housing 670, and the device connection circuit board 610, the reference device seat 620, and the DUT seat 630 are mounted within the housing 670.

Specifically, the device connection circuit board 610, the reference device seat 620, and the DUT seat 630 are positioned within the housing 670 to form a testing socket. When a DUT is under test, it can be directly placed into the DUT seat 630 of the testing socket for testing. The integrated testing socket facilitates operation and improves testing efficiency.

In some embodiments, the testing apparatus 600 further includes a test circuit board 680, and a test circuit board connector 681 mounted on the front or back surface of the device connection circuit board 610. The test circuit board connector 681 is used to couple the test circuit board 680 with the device connection circuit board 610. The device connection circuit board 610 can receive power supply from the test circuit board 680 through the test circuit board connector 681, receive control or driving signals from the test circuit board 680, or send feedback signals or test data/results to the test circuit board 680. In specific implementations, the test circuit board 680 can be a high-performance multilayer board providing driving signals to the device connection circuit board 610. The test circuit board 680 can also be used for electrical testing of the DUT and to verify its functionality, performance, and reliability.

In some embodiments, the testing apparatus 600 further includes a test host 690, which is coupled to the test circuit board 680, and used to control the test circuit board 680 to test the DUT via the test circuit board 680 and the device connection circuit board 610. The test host 690 can implement various desired functions, such as collecting, storing, and analyzing data. Thus, the test host 690 can perform various desired tests on the DUT, such as parameter testing, functional testing, performance testing, fault detection, reliability testing, and so on.

The discussion herein included numerous illustrative figures that showed various portions of a testing apparatus for OTA testing. For illustrative clarity, such figures did not show all aspects of each example assembly. Any of the example assemblies and/or methods provided herein may share any or all characteristics with any or all other assemblies and/or methods provided herein.

Various embodiments have been described herein with reference to the accompanying drawings. It will, however, be evident that various modifications and changes may be made thereto, and additional embodiments may be implemented, without departing from the broader scope of the invention as set forth in the claims that follow. Further, other embodiments will be apparent to those skilled in the art from consideration of the specification and practice of one or more embodiments of the invention disclosed herein. It is intended, therefore, that this application and the examples herein be considered as exemplary only, with a true scope and spirit of the invention being indicated by the following listing of exemplary claims.

What is claimed is:

1. A testing apparatus, comprising:
a device connection circuit board having a front surface, and a back surface；
a reference device seat supported at a front side of the device connection circuit board, wherein the reference device seat comprises:
a reference device cavity for receiving a reference device; and
a first set of openings formed at a side of the reference device cavity away from the device connection circuit board, and configured to expose a set of RF ports of the reference device received within the reference device cavity; and
a device under test (DUT) seat supported at the front side of the device connection circuit board and farther away from the device connection circuit board than the reference device seat; wherein the DUT seat at least overlaps with the reference device seat at the first set of openings of the reference device seat, and wherein the DUT seat comprises:
a DUT cavity for receiving a DUT; and
a second set of openings formed at a side of the DUT cavity facing the device connection circuit board and in a region of the DUT seat overlapping with the reference device seat, wherein the second set of openings are aligned with the first set of openings; and wherein the second set of openings are configured to expose a set of RF ports of the DUT received within the DUT cavity to allow communication between the DUT and the reference device through the two sets of RF ports aligned with each other.

2. The testing apparatus of claim 1, wherein the DUT cavity comprises:
a guide member formed within the DUT cavity, and configured to guide the DUT to move to a predetermined test position within the DUT cavity to align the set of RF ports of the DUT with the second set of openings.

3. The testing apparatus of claim 2, wherein the guide member comprises:
at least one inclined surface inclined relative to a bottom of the DUT cavity to guide the DUT to slide down to the predetermined test position.

4. The testing apparatus of claim 2, wherein the DUT seat further comprises:
a device loading opening connected to the DUT cavity to allow the DUT to be received within the DUT cavity through the device loading opening;
wherein the at least one inclined surface is located between the device loading opening and the bottom of the DUT cavity.

5. The testing apparatus of claim 1, wherein the testing apparatus comprises a test region between the first set of openings and the second set of openings, and the testing apparatus further comprises:
a shielding component mounted around the test region, and configured to shield external electromagnetic signals from entering the test region.

6. The testing apparatus of claim 5, wherein the shielding component comprises:
a shielding tape adhered to the reference device seat and the DUT seat and between the first set of openings and the second set of openings, and the shielding tape is formed such that the first set of openings and the second set of openings are exposed from the shielding tape.

7. The testing apparatus of claim 6, wherein the shielding component further comprises:
a support member mounted around the test region, and configured to support the shielding tape around the test region in a predetermined shape.

8. The testing apparatus of claim 7, wherein the support member surrounds the test region.

9. The testing apparatus of claim 1, wherein the reference device is removably mounted within the reference device cavity.

10. The testing apparatus of claim 1, wherein the reference device seat further comprises:
a first set of electrical connection components for electrically coupling the reference device received within the reference device cavity to the device connection circuit board; and
wherein the DUT seat further comprises:
a second set of electrical connection components for electrically coupling the DUT received within the DUT cavity to the device connection circuit board.

11. The testing apparatus of claim 10, wherein the first set of electrical connection components comprises:
a first set of pogo pins located on the side of the reference device cavity away from the device connection circuit board, and including a first set of contacts connectable to the reference device and a second set of contacts opposite to the first set of contacts;
a second set of pogo pins located between the reference device seat and the device connection circuit board, including a third set of contacts connected to the device connection circuit board and a fourth set of contacts opposite to the third set of contacts; and
a flexible connector extending from a front surface to a back surface of the reference device seat, and configured to couple the second set of contacts with the fourth set of contacts.

12. The testing apparatus of claim 10, wherein the second set of electrical connection components comprises:
a third set of pogo pins located between the DUT seat and the device connection circuit board, and configured to couple the DUT with the device connection circuit board.

13. The testing apparatus of claim 1, wherein the testing apparatus further comprises a housing, wherein the device connection circuit board, the reference device seat, and the DUT seat are mounted within the housing.

14. The testing apparatus of claim 1, wherein the testing apparatus further comprises:
the reference device, and the reference device is fixed within the reference device cavity.

15. The testing apparatus of claim 1, wherein the testing apparatus further comprises:
a test circuit board; and
a test circuit board connector mounted on the front or back surface of the device connection circuit board, and configured to couple the test circuit board with the device connection circuit board.

16. The testing apparatus of claim 15, wherein the testing apparatus further comprises:
a test host coupled to the test circuit board, and configured to control the test circuit board to test the DUT via the test circuit board and the device connection circuit board.
